(19) United States
(12) Patent Application Publication
(10) Pub. No.: US 2026/0003107 A1
(43) Pub. Date: Jan. 1, 2026

(54) LIGHT ABSORBING STRUCTURE AND DISPLAY DEVICE

(71) Applicant: AUO Corporation, Hsinchu City (TW)

(72) Inventors: Wang-Shuo Kao, Hsinchu City (TW); Wei-Ming Cheng, Hsinchu City (TW); Hao Shiun Yang, Hsinchu City (TW); Jian-Fu Chen, Hsinchu City (TW); Shang-Chiang Lin, Hsinchu City (TW); Chao-Wei Yeh, Hsinchu City (TW); Ya-Ling Hsu, Hsinchu City (TW); Chen-Hsien Liao, Hsinchu City (TW); Jenn-Jia Su, Hsinchu City (TW); Yang-En Wu, Hsinchu City (TW)

(73) Assignee: AUO Corporation, Hsinchu City (TW)

(21) Appl. No.: 18/945,538

(22) Filed: Nov. 13, 2024

(30) Foreign Application Priority Data
Jun. 27, 2024 (TW) 113124089

(51) Int. Cl. G02B 5/00; G02B 1/11; G02B 5/30; H01L 25/075; H01L 33/44; H01L 33/58

(52) U.S. Cl. CPC G02B 5/003; G02B 1/11; G02B 5/3016; H01L 25/0753; H10H 20/84; H10H 20/855

(57) ABSTRACT

A light absorbing structure for a display device includes a light control layer and a first optical compensation film overlapped with the light control layer. An angle between an absorption axis of the light control layer and a normal direction of the light control layer is less than or equal to 10 degrees. An absolute value of an in-plane retardation R0 of the first optical compensation film is greater than 130 nm and less than 550 nm.

### CROSS-REFERENCE TO RELATED APPLICATION

This application claims the priority benefit of Taiwan application serial no. 113124089, filed on Jun. 27, 2024. The entirety of the above-mentioned patent application is hereby incorporated by reference herein and made a part of this specification.

### BACKGROUND

### Technical Field

The disclosure relates to a light absorbing structure and a display device.

### Description of Related Art

A transparent display device is a light-transmitting display device, and a user can see the image information displayed as well as the background information behind the display device. Transparent displays have many uses, such as vending machine windows, car windows, home windows, and storefront windows.

When a display device displays an image, light emitted by a light source inside the display device may be reflected inside the display device, causing light leakage from the back side of the display device. Especially when the viewing angle is large, the image displayed by the display device may be reflected at the interface between the display device and the air. The reflected light may leak out from the back of the display device and affect the visual effect from the back of the display device.

### SUMMARY

The disclosure provides a light absorbing structure for a display device, the light absorbing structure including a light control layer and an optical compensation film overlapped with the light control layer, so as to decrease the back-side light leakage of the display device.

At least one embodiment of the disclosure provides a light absorbing structure for a display device including a light control layer and a first optical compensation film overlapped with the light control layer. An angle between an absorption axis of the light control layer and a normal direction of the light control layer is less than or equal to 10 degrees. An absolute value of an in-plane retardation R0 of the first optical compensation film is greater than 130 nm and less than 550 nm.

At least one embodiment of the disclosure further provides a display device including a display panel and a light absorbing structure. The display panel has a first surface and a second surface opposite to the first surface, and the first surface is a display surface of the display panel. The light absorbing structure is located on the first surface or the second surface of the display panel. The light absorbing structure includes a light control layer and a first optical compensation film overlapped with the light control layer. An angle between an absorption axis of the light control layer and a normal direction of the light control layer is less than or equal to 10 degrees. An absolute value of an in-plane retardation R0 of the first optical compensation film is greater than 130 nm and less than 550 nm.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a display device according to an embodiment of the disclosure.

FIG. 2 is a schematic cross-sectional view of a display device according to an embodiment of the disclosure.

FIG. 3 is a schematic cross-sectional view of a display device according to an embodiment of the disclosure.

FIG. 4 is a schematic cross-sectional view of a display device according to an embodiment of the disclosure.

FIG. 5 is a schematic cross-sectional view of a display device according to an embodiment of the disclosure.

FIG. 6A is a schematic cross-sectional view of a light control layer of a display device according to an embodiment of the disclosure.

FIG. 6B is a schematic cross-sectional view of a liquid crystal molecule in the light control layer according to an embodiment of the disclosure.

FIG. 7 is a simulation graph of back-side light leakage brightness of a display device and a phase retardation Rth and an in-plane retardation R0 in a thickness direction a first optical compensation film according to an embodiment of the disclosure.

FIG. 8A is a relative brightness distribution of a display device at various viewing angles according to an embodiment of the disclosure.

FIG. 8B is a curve chart of an elevation angle (theta) and back-side light leakage of a display device when an azimuth angle (phi) is 0°.

FIG. 9A is a relative brightness distribution of a display device at various viewing angles according to an embodiment of the disclosure.

FIG. 9B is a curve chart of an elevation angle (theta) and back-side light leakage of a display device when an azimuth angle (phi) is 0°.

FIG. 10A is a relative brightness distribution of a display device at various viewing angles according to an embodiment of the disclosure.

FIG. 10B is a curve chart of an elevation angle (theta) and back-side light leakage of a display device when an azimuth angle (phi) is 0°.

### DESCRIPTION OF THE EMBODIMENTS

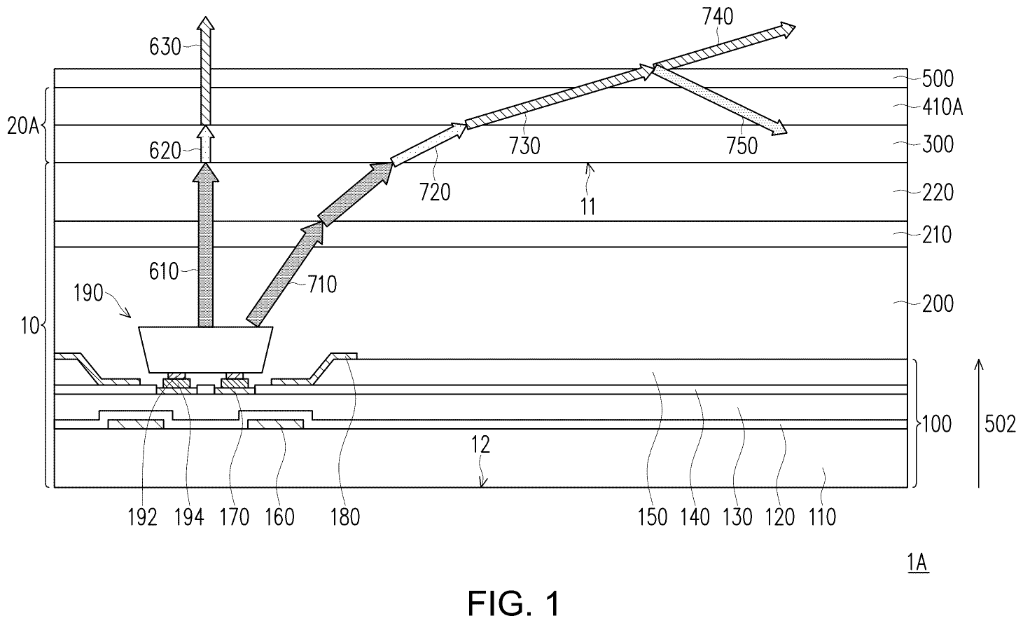

FIG. 1 is a schematic cross-sectional view of a display device 1A according to an embodiment of the disclosure. With reference to FIG. 1, the display device 1A includes a display panel 10, a light absorbing structure 20A, and an anti-reflective film 500. The light absorbing structure 20A is disposed in the display panel 10 or is disposed on the display panel 10. The anti-reflective film 500 is disposed on an outer side of the display panel 10 or an outer side of the light absorbing structure 20A.

The display panel 10 has a first surface 11 and a second surface 12 (also referred to as a back surface) opposite to the first surface 11 (also referred to as a display surface). The display panel 10 is a transparent display panel in any form, such as a transparent liquid crystal display panel, a transparent micro light-emitting diode display panel, a transparent organic light-emitting diode display panel, or other types of display panels. In this embodiment, the display panel 10 is a transparent micro light-emitting diode display panel. In some embodiments, the light absorbing structure 20A is located on the first surface 11 of the display panel 10 and is located between the anti-reflective film 500 and the display panel 10.

The display panel 10 includes a circuit substrate 100, a light-emitting diode 190, a packaging layer 200, and a cover plate 220. A surface of the circuit substrate 100 facing away from the cover plate 220 is the second surface 12, and a surface of the cover plate 220 facing away from the circuit substrate 100 is the first surface 11. The light-emitting diode 190 and the packaging layer 200 are located between the circuit substrate 100 and the cover plate 220. The circuit substrate 100 includes a substrate 110, an insulating layer 120, an insulating layer 130, an insulating layer 140, an insulating layer 150, a signal line 160, a pad 170, and a reflective layer 180.

The substrate 110 and the cover plate 220 are, for example, rigid substrates, and their materials may be glass, quartz, organic polymer, or other applicable materials. However, the disclosure is not limited thereto, and in other embodiments, the substrate 110 and the cover plate 220 may also be flexible substrates or stretchable substrates. For instance, materials of the flexible substrates and the stretchable substrates include, for example, polyimide (PI), polydimethylsiloxane (PDMS), polyethylene terephthalate (PET), polyethylene naphthalate (PEN), polyester (PES), polymethylmethacrylate (PMMA), polycarbonate (PC), polyurethane (PU), or other suitable materials.

The insulating layer 120, the insulating layer 130, the insulating layer 140, and the insulating layer 150 are sequentially disposed on the substrate 110. In some embodiments, materials and amount of the insulating layers on the substrate 110 may be adjusted according to needs. The signal line 160 is disposed on the substrate 110. In some embodiments, a position of the signal line 160 may be adjusted according to needs. For instance, the signal line 160 may be disposed between two insulating layers.

The insulating layer 150 has an opening for accommodating the light-emitting diode 190, and the reflective layer 180 is optionally disposed on a surface of the opening, so that light-emitting efficiency of the display device 1A is improved.

The light-emitting diode 190 is electrically connected to the pad 170 of the circuit substrate 100. For instance, an electrode 192 of the light-emitting diode 190 is connected to the pad 170 through a solder 194. In other embodiments, the light-emitting diode 190 is connected to the pad 170 via a conductive glue. The light-emitting diode 190 may be any type of light-emitting diodes, and the color and type of the light-emitting diode 190 are not limited in the disclosure.

The packaging layer 200 covers the light-emitting diode 190. The cover plate 220 is combined with the packaging layer 200 through a transparent adhesive layer 210. A material of the transparent adhesive layer 210 is, for example, optical clear resin (OCR), optical clear adhesive (OCA), pressure sensitive adhesive (PSA), or other suitable adhesive materials.

The light absorbing structure 20A is located outside the display panel 100 or inside the display panel 100. In this embodiment, the light absorbing structure 20A is located on the first surface 11 of the display panel 100, but the disclosure is not limited thereto. In other embodiments, the light absorbing structure 20A is located on the second surface 12 of the display panel 100 or between the substrate 110 and the cover plate 220.

The light absorbing structure 20A includes a light control layer 300 and a first optical compensation film 410A overlapped with the light control layer 300. In this embodiment, the light control layer 300 is located between the first optical compensation film 410A and the first surface 11 of the cover plate 220.

The light control layer 300 may be a thin film or a liquid crystal cell, which is configured to absorb light of a specific polarization state. Generally, unpolarized light includes P waves and S waves, and the light control layer 300 is configured to have a higher absorption rate for P waves than for S waves in the light emitted by the display panel 100. Therefore, after passing through the light control layer 300, the light penetrates and becomes polarized light with S wave as the main component. In some embodiments, the light control layer 300 has a transmittance of less than 25% for P waves at an elevation angle of 30 degrees in visible light and a transmittance of more than 35% for S waves at an elevation angle of 30 degrees in visible light.

In some embodiments, by adjusting an absorption axis of the light control layer 300, the light control layer 300 may absorb P waves while allowing S waves to penetrate. To be specific, in this embodiment, an angle between the absorption axis of the light control layer 300 and a normal direction 502 (i.e., Z-axis direction) of the light control layer is less than or equal to 10 degrees, preferably 0 degrees. In some embodiments, in addition to having the absorption axis substantially parallel to the normal direction 502, the light control layer 300 may also have another absorption axis (e.g., the absorption axis parallel to the X-axis) on a plane of the light control layer 300 that is perpendicular to the normal direction 502. Therefore, the light control layer 300 may absorb the polarization state of the light in the Z-axis direction and the polarization state in the X-axis direction.

The first optical compensation film 410A may also be referred to as a retardation film. Refractive indices of the first optical compensation film 410A in the xyz directions are nx1, ny1, and nz1, respectively, where the direction of nz1 is parallel to a normal direction of the first optical compensation film 410A. An in-plane retardation R0 of the first optical compensation film 410A is equal to (nx1−ny1)d1, where d1 is a thickness of the first optical compensation film 410A. In some embodiments, d1 is 100 nm to 200 μm. In this embodiment, an absolute value of the in-plane retardation R0 of the first optical compensation film 410A is greater than 130 nm and less than 550 nm. In this embodiment, the light absorbing structure 20A includes a single-layer retardation film (i.e., the first optical compensation film 410A), but the disclosure is not limited thereto. In other embodiments, the light absorbing structure 20A includes multiple layers of retardation films.

In some embodiments, the absolute value of the in-plane retardation R0 of the first optical compensation film 410A is greater than or equal to an absolute value of an in-plane retardation R0 of a ¼ wavelength wave plate (approximately 137.5 nm). In some embodiments, the first optical compensation film 410A may be a ½ (or x+½) wavelength wave plate, where x is an integer. In this case, the absolute value of the in-plane retardation R0 of the first optical compensation film 410A is approximately 275 nm.

The anti-reflective film 500 is optionally disposed on the first optical compensation film 410A. In this embodiment, the anti-reflective film 500 is located on the light absorbing structure 20A located between the anti-reflective film 500 and the display panel 10. The anti-reflective film 500 may have a single-layer structure or a multi-layer structure. In some embodiments, the anti-reflective film 500 may be a moth-eye anti-reflective coating.

FIG. 1 shows several paths of light emitted from the light-emitting diode 190. A light ray 610 is emitted in a direction perpendicular to the first surface 11, while a light ray 710 is emitted in a direction with a large angle. The light ray 610 and the light ray 710 are unpolarized light rays. The light control layer 300 absorbs most of the P waves in the light ray 710. In some embodiments, a light ray 720 passing through the light control layer 300 is S-wave linearly polarized light or S-wave polarized light mixed with a small amount of P-wave. In some embodiments, when the absorption axis of the light control layer 300 is not completely parallel to the normal direction 502, part of a light ray 620 may also be absorbed.

The polarization types of the light ray 620 and the light ray 720 are changed after passing through the first optical compensation film 410A, and the light ray 620 and the light ray 720 are transformed into a light ray 630 and a light ray 730, respectively. In some embodiments, since the light ray 620 and the light ray 720 enter the first optical compensation film 410A at different angles and are transformed into the light ray 630 and the light ray 730, the light ray 630 and the light ray 730 may have different degrees of retardation. In some embodiments, at an interface between the first optical compensation film 410A and the anti-reflective film 500 (or air in the absence of the anti-reflective film 500), the light ray 730 is, for example, circularly polarized light or elliptically polarized light.

Since the light ray 630 leaves the first optical compensation film 410A in a nearly vertical direction, the light ray 630 is not significantly reflected at the interface between the first optical compensation film 410A and the anti-reflective film 500 (or air). In contrast, since the light ray 730 reaches an interface between the anti-reflective film 500 and air (in the absence of the anti-reflective film 500, the interface between the first optical compensation film 410A and air) at a larger angle, at the interface between the first optical compensation film 410A and air or at the interface between the anti-reflective film 500 and air, the light ray 730 is divided into a light ray 740 that leaves the first optical compensation film 410A and enters air and a reflected light ray 750.

The reflected light ray 750 has a circular polarization direction opposite to that of the light ray 730, and after passing through the first optical compensation film 410A again, the first optical compensation film 410A converts the light ray 750 into a linearly polarized light of a P wave or a polarized light of a P wave mixed with a small amount of an S wave.

Since the light control layer 300 has a relatively large absorptivity for P-waves, most of the light ray 750 is absorbed by the light control layer 300, so that the back light leakage of the display device 1A is decreased.

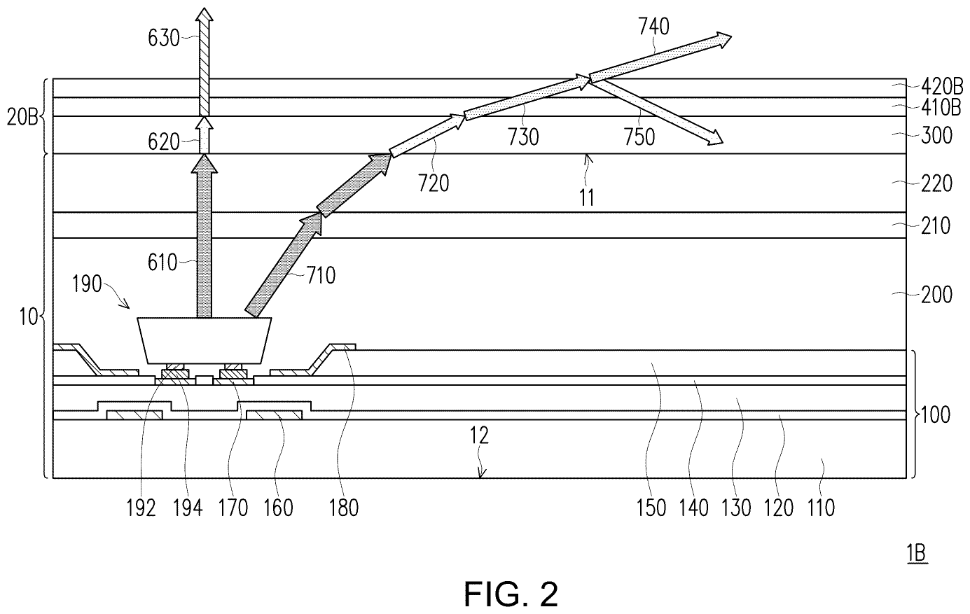

FIG. 2 is a schematic cross-sectional view of a display device 1B according to an embodiment of the disclosure. It should be noted that the reference numerals and a part of the contents in the embodiment of FIG. 1 are also used to describe the embodiment of FIG. 2, in which the same reference numerals are used to represent identical or similar elements, and thus descriptions of the same technical contents are omitted. Please refer to the descriptions of the previous embodiments for the omitted part, which will not be repeated hereinafter.

The difference between the display device 1B of FIG. 2 and the display device 1A of FIG. 1 is that a light absorbing structure 20B of the display device 1B includes the light control layer 300, a first optical compensation film 410B overlapped with the light control layer 300, and a second optical compensation film 420B.

The second optical compensation film 420B is located on the first optical compensation film 410B located between the light control layer 300 and the second optical compensation film 420B.

In this embodiment, the first optical compensation film 410B and the second optical compensation film 420B may both be referred to as retardation films. Refractive indices of the first optical compensation film 410B in the xyz directions are nx1, ny1, and nz1, respectively, where the direction of nz1 is parallel to the normal direction of the first optical compensation film 410B. Refractive indices of the second optical compensation film 420B in the xyz directions are nx2, ny2, and nz2, respectively, where the direction of nz2 is parallel to a normal direction of the second optical compensation film 420B. An in-plane retardation R0 of the first optical compensation film 410B is equal to (nx1−ny1)d1, where d1 is a thickness of the first optical compensation film 410B. An in-plane retardation R0 of the second optical compensation film 420B is equal to (nx2−ny2)d1, where d2 is a thickness of the second optical compensation film 420B. In some embodiments, d1 and d2 are each 100 nm to 200 μm. In some embodiments, absolute values of the in-plane retardation R0 of the first optical compensation film 410B and the in-plane retardation R0 of the second optical compensation film 420B are greater than 130 nm and less than 550 nm. For instance, the absolute values of the in-plane retardation R0 of the first optical compensation film 410B and the in-plane retardation R0 of the second optical compensation film 420B are both in the range of 195 nm to 350 nm, for example, approximately 270 nm. In some embodiments, the absolute values of the in-plane retardation R0 of the first optical compensation film 410B and the in-plane retardation R0 of the second optical compensation film 420B are greater than or equal to the absolute value of the in-plane retardation R0 of the ¼ wavelength wave plate (approximately 137.5 nm). In some embodiments, the first optical compensation film 410B and the second optical compensation film 420B may both be referred to as ½ (or x+½) wavelength wave plates. An angle between a slow axis of the first optical compensation film 410B and a slow axis of the second optical compensation film 420B is in the range of 30° to 60°, for example, approximately 45 degrees.

FIG. 2 shows several paths of light emitted from the light-emitting diode 190. The light ray 610 is emitted in a direction perpendicular to the first surface 11, while the light ray 710 is emitted in a direction with a large angle. The light ray 610 and the light ray 710 are unpolarized light rays. The light control layer 300 absorbs most of the P waves in the light ray 710. In some embodiments, the light ray 720 passing through the light control layer 300 is S-wave linearly polarized light or S-wave polarized light mixed with a small amount of P-wave. In some embodiments, when the absorption axis of the light control layer 300 is not completely parallel to the normal direction, part of the light ray 620 may also be absorbed.

The polarization types of the light ray 620 and the light ray 720 are changed after passing through the first optical compensation film 410B and the second optical compensation film 420B, and the light ray 620 and the light ray 720 are transformed into the light ray 630 and the light ray 730, respectively. In some embodiments, since the light ray 620 and the light ray 720 enter the first optical compensation film 410B and the second optical compensation film 420B at different angles and are transformed into the light ray 630 and the light ray 730, the light ray 630 and the light ray 730 may have different degrees of retardation. In some embodiments, at an interface between the second optical compensation film 420B and air, the light ray 730 is, for example, linearly polarized light of P wave or polarized light of P wave mixed with a small amount of S wave.

Since the light ray 630 leaves the second optical compensation film 420B in a nearly vertical direction, the light ray 630 is not significantly reflected at the interface between the second optical compensation film 420B and air. In contrast, since the light ray 730 reaches the interface between the second optical compensation film 420B and air at a relatively large angle, the light ray 730 is divided into the light ray 740 leaving the second optical compensation film 420B and the reflected light ray 750 at the interface between the second optical compensation film 420B and air. In this embodiment, the P wave has a higher transmittance at the interface between the second optical compensation film 420B and air. Since the light ray 730 is substantially a P wave at the interface between the second optical compensation film 420B and air, most of the light ray 730 may leave the first optical compensation film 410A and form the light ray 740.

Since most of the P waves leave the first optical compensation film 410A, the reflected light ray 750 includes S waves mixed with a small amount of P waves, and after passing through the first optical compensation film 410B and the second optical compensation film 420B again, the first optical compensation film 410B and the second optical compensation film 420B convert the light ray 750 into polarized light with P waves mixed with a small amount of S waves.

Since the light control layer 300 has a relatively large absorptivity for P-waves, most of the light ray 750 is absorbed by the light control layer 300, so that the back light leakage of the display device 1B is decreased.

With reference to FIG. 2 together, the light ray emitted by the light-emitting diode 190 sequentially passes through the light control layer 300 and a compensation structure composed of the first optical compensation film 410B and the second optical compensation film 420B. Table 1, Table 2, and Table 3 show the states of the light rays in each film layer of the display device 1B in an embodiment of the disclosure. In Table 1, Table 2, and Table 3, it is assumed that film 5 layers other than the light control layer 300 and the compensation structure (i.e., the first optical compensation film 410B and the second optical compensation film 420B) do not absorb light, the in-plane retardation R0 of the first optical compensation film 410B and the in-plane retardation R0 of the second optical compensation film 420B are 270 nm, and the angle between the slow axis of the first optical compensation film 410B and the slow axis of the second optical compensation film 420B is 45 degrees. In the embodiments of Table 1, Table 2, and Table 3, the transmittance of the display device 1B at a normal viewing angle is 76%. Table 1 shows the percentage of light ray emitted by the light-emitting diode that remains after passing through each film layer at an output angle of 30 degrees.

TABLE 1

| | P waves in | S waves in |
|---|---|---|
| | light ray | light ray |
| Light ray emitted by a light-emitting diode | 100.000% | 100.000% |
| Light ray at the interface between the light | 12.512% | 89.095% |
| control layer and the compensation structure | | |
| after passing through the light control layer | | |
| Light ray at the interface between the | 89.095% | 12.512% |
| compensation structure and air after passing | | |
| through the compensation structure | | |
| Light ray entering air from the front | 88.204% | 10.010% |
| Proportion of light ray entering air | 49.110% | |
| from the front to the original | | |

Table 2 shows the percentage of light ray emitted by the light-emitting diode that is reflected at the interface between the compensation structure and air at a reflection angle of 30 degrees and then re-passes through each film layer at an incident angle of 30 degrees. Following the results in Table 1, approximately 0.891% of the P-wave and 2.502% of the S-wave are reflected at the interface between the compensation structure and air.

TABLE 2

| | P waves in | S waves in |
|---|---|---|
| | light ray | light ray |
| Light ray reflected at the interface between | 0.891% | 2.502% |
| the compensation structure and air | | |
| Light ray at the interface between the light | 2.502% | 0.891% |
| control layer and the compensation structure | | |
| after passing through the compensation | | |
| structure | | |
| Light ray passing through the light control | 0.313% | 0.793% |
| layer and leaving the light control layer | | |
| Light ray in the substrate (glass) | 0.313% | 0.794% |
| Light ray that passes through the substrate | 0.310% | 0.64% |
| (glass) and enters air from the back side | | |
| (second side) | | |
| Proportion of light rays entering air | 0.472% | |
| from the back | | |

It can be seen from Table 1 and Table 2 that the light control layer 300 and the compensation structure (i.e., the first optical compensation film 410B and the second optical compensation film 420B) may significantly reduce the back-side light leakage, so that the visual effect of the display device is improved.

With reference to FIG. 2 together, the external light ray incident on the display device 1B from the back side of the display device 1B may leave from the front side of the display device 1B after passing through each film layer. Table 3 shows the percentage of external light ray that remains after passing through each film layer at an output angle of 30 degrees. In Table 3, it is assumed that the light ray does not pass through any opaque components.

TABLE 3

| | P waves in | S waves in |
|---|---|---|
| | light ray | light ray |
| External light ray | 100.000% | 100.000% |
| External light ray that enters the display | 99.000% | 80.000% |
| device from the back after passing through | | |
| the interface between the substrate and air | | |
| External light ray passing through the | 99.000% | 80.000% |
| substrate | | |
| External light ray that passes through the | 99.000% | 80.000% |
| transparent plastic layer and enters the light | | |
| control layer | | |
| External light ray at the interface between the | 12.387% | 71.276% |
| light control layer and the compensation | | |
| structure after passing through the light | | |
| control layer | | |
| External light ray at the interface between the | 71.276 | 12.387 |
| compensation structure and air after passing | | |
| through the compensation structure | | |
| External light ray entering air from the front | 70.563% | 9.910% |
| Proportion of light ray entering air from the | 40.240% | |
| front to the original | | |

From Table 3, it can be seen that the display device 1B has a transmittance of approximately 40% at a viewing angle (elevation angle (theta)) of 30 degrees.

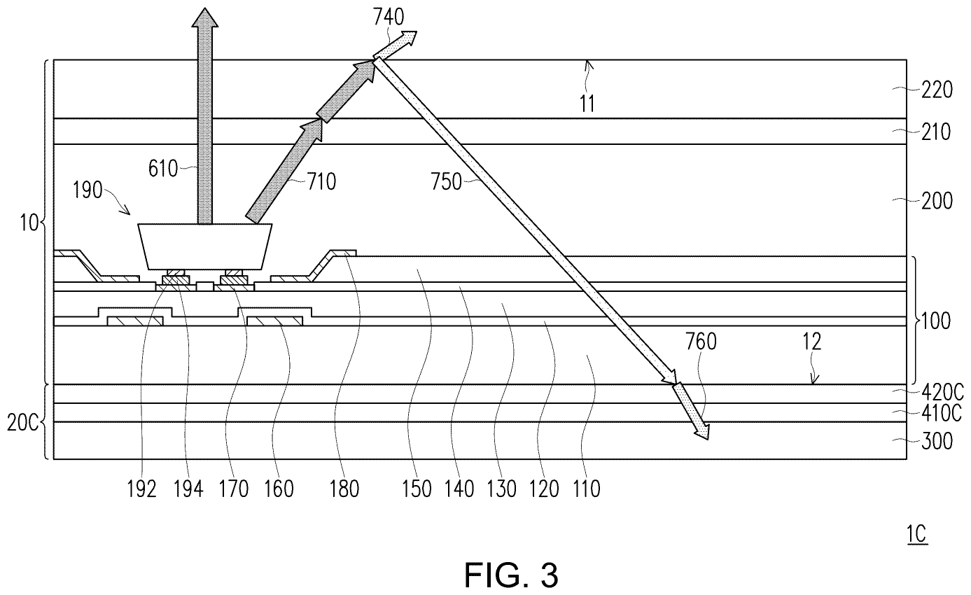

FIG. 3 is a schematic cross-sectional view of a display device 1C according to an embodiment of the disclosure. It should be noted that the reference numerals and a part of the contents in the embodiment of FIG. 2 are also used to describe the embodiment of FIG. 3, in which the same reference numerals are used to represent identical or similar elements, and thus descriptions of the same technical contents are omitted. Please refer to the descriptions of the previous embodiments for the omitted part, which will not be repeated hereinafter.

The difference between the display device 1C of FIG. 3 and the display device 1B of FIG. 2 is that a light absorbing structure 20C of the display device 1C includes the light control layer 300, a first optical compensation film 410C overlapped with the light control layer 300, and a second optical compensation film 420C. The light absorbing structure 20C is located on the second surface 12, and the first optical compensation film 410C and the second optical compensation film 420C are located between the light control layer 300 and the circuit substrate 100. The first optical compensation film 410C is located between the light control layer 300 and the second optical compensation film 420C. In some embodiments, the display device 1C further includes an anti-reflective film (not shown) disposed on the first surface 11 of the display panel 10, where the display panel 10 is located between the anti-reflective film and the light absorbing structure 20C.

In this embodiment, the first optical compensation film 410C and the second optical compensation film 420C may both be referred to as retardation films. Refractive indices of the first optical compensation film 410C in the xyz directions are nx1, ny1, and nz1, respectively, where the direction of nz1 is parallel to a normal direction of the first optical compensation film 410C. Refractive indices of the second optical compensation film 420C in the xyz directions are nx2, ny2, and nz2, respectively, where the direction of nz2 is parallel to a normal direction of the second optical compensation film 420C. An in-plane retardation R0 of the first optical compensation film 410C is equal to (nx1−ny1)d1, where d1 is a thickness of the first optical compensation film 410C. An in-plane retardation R0 of the second optical compensation film 420C is equal to (nx2−ny2)d1, where d2 is a thickness of the second optical compensation film 420C. In some embodiments, absolute values of the in-plane retardation R0 of the first optical compensation film 410C and the in-plane retardation R0 of the second optical compensation film 420C are greater than 130 nm and less than 550 nm. For instance, the absolute values of the in-plane retardation R0 of the first optical compensation film 410C and the in-plane retardation R0 of the second optical compensation film 420C are both in the range of 195 nm to 350 nm, for example, approximately 270 nm. In some embodiments, the absolute values of the in-plane retardation R0 of the first optical compensation film 410C and the in-plane retardation R0 of the second optical compensation film 420B are greater than or equal to the absolute value of the in-plane retardation R0 of the ¼ wavelength wave plate (approximately 137.5 nm). In some embodiments, the first optical compensation film 410C and the second optical compensation film 420C may both be referred to as ½ (or x+½) wavelength wave plates, and x is an integer. An angle between a slow axis of the first optical compensation film 410C and a slow axis of the second optical compensation film 420C is in the range of 30° to 60°, for example, approximately degrees.

FIG. 3 shows several paths of light emitted from the light-emitting diode 190. The light ray 610 is emitted in a direction perpendicular to the first surface 11, while the light ray 710 is emitted in a direction with a large angle. The light ray 610 and the light ray 710 are unpolarized light rays.

Since the light ray 610 leaves the cover plate 220 in a nearly vertical direction, the light ray 610 may not experience significant reflection at an interface between the cover plate 220 and air. In contrast, since the light ray 710 reaches the interface between the cover plate 220 and air at a relatively large angle, the light ray 710 is divided into the light ray 740 leaving the cover plate 220 and the reflected light ray 750 at the interface between the cover plate 220 and air. In this embodiment, the P wave has a higher transmittance at the interface between the cover plate 220 and air. Therefore, the reflected light ray 750 is linearly polarized light of S wave or polarized light of S wave mixed with P wave whose amount is smaller than that of S wave, and the light ray 740 is a linearly polarized light of a P wave or a polarized light in which a P wave is mixed with a smaller amount of an S wave than a P wave.

The reflected light ray 750 passes through the cover plate 220 again and reaches the interface between the substrate 110 and the second optical compensation film 420C. Next, the polarization type of the light ray 750 is changed after light ray 750 passes through the second optical compensation film 420C and the first optical compensation film 410C, so that it is converted into the light ray 760. In some embodiments, at an interface between the first optical compensation film 410C and the light control layer 300, the light ray 760 is, for example, linearly polarized light of P wave or polarized light of P wave mixed with a small amount of S wave.

The light control layer 300 absorbs most of the P waves in the light ray 760, so that most of the light ray 760 is absorbed by the light control layer 300, and that the back light leakage of the display device 1C is decreased.

With reference to FIG. 3 together, the light ray emitted by the light-emitting diode 190 may enter air after passing through the cover plate 220. Table 4, Table 5, and Table 6 show the states of the light rays in each film layer of the display device 1C in an embodiment of the disclosure. In Table 4, Table 5, and Table 6, it is assumed that film layers other than the light control layer 300 and the compensation structure (i.e., the first optical compensation film 410C and the second optical compensation film 420C) do not absorb light, the in-plane retardation R0 of the first optical compensation film 410C and the in-plane retardation R0 of the second optical compensation film 420C are 270 nm, and the angle between the slow axis of the first optical compensation film 410C and the slow axis of the second optical compensation film 420C is 45 degrees. In the embodiments of Table 4, Table 5, and Table 6, the transmittance of the display device 1C at a normal viewing angle is 76%. Table 4 shows the percentage of light ray emitted by the light-emitting diode that remains after passing through each film layer at an output angle of 30 degrees.

TABLE 4

| | P waves in | S waves in |
|---|---|---|
| | light ray | light ray |
| Light ray emitted by a light-emitting diode | 100.000% | 100.000% |
| Light ray at the interface between the cover | 100.000% | 100.000% |
| plate and air after passing through the cover | | |
| plate | | |
| Light ray entering air from the front | 99.000% | 80.000% |
| Proportion of light ray entering air from the | 89.500% | |
| front to the original | | |

It can be seen from Table 4 that the light absorbing structure 20C of the display device 1C is disposed on the second surface 12 of the display panel 100, which can increase the amount of light ray entering air from the front.

Table 5 shows the percentage of light ray emitted by the light-emitting diode that is reflected at the interface between the cover plate and air at a reflection angle of 30 degrees and then re-passes through each film layer at an incident angle of 30 degrees. Following the results in Table 4, approximately 1% of the P-wave and 20% of the S-wave are reflected at the interface between the cover plate and air.

TABLE 5

| | P waves in | S waves in |
|---|---|---|
| | light ray | light ray |
| Light ray reflected at the interface between | 1.000% | 20.000% |
| the cover plate (glass) and air | | |
| Light ray at the interface between the | 1.000% | 20.000% |
| substrate and the compensation structure | | |
| after passing through the substrate (glass) | | |
| Light ray at the interface between the | 20.000% | 1.000% |
| compensation structure and the light control | | |
| layer after passing through the compensation | | |
| structure | | |
| Light ray at the interface between the light | 2.502% | 0.890% |
| control layer and air after passing through the | | |
| light control layer | | |
| Light ray that enters air from the back after | 2.477% | 0.712% |
| passing through the light control layer | | |
| Proportion of light rays entering air from the | 1.595% | |
| back | | |

It can be seen from Table 4 and Table 5 that the light control layer 300 and the compensation structure (i.e., the first optical compensation film 410C and the second optical compensation film 420C) may significantly reduce the back-side light leakage, so that the visual effect of the display device 1C is improved.

With reference to FIG. 3 together, the external light ray incident on the display device 1C from the back side of the display device 1C may leave from the front side of the display device 1C after passing through each film layer. Table 6 shows the percentage of external light ray that remains after passing through each film layer at an output angle of 30 degrees in an embodiment. In Table 6, it is assumed that the light ray does not pass through any opaque components.

TABLE 6

| | P waves in | S waves in |
|---|---|---|
| | light ray | light ray |
| External light ray | 100.000% | 100.000% |
| External light ray that enters the display | 99.000% | 80.000% |
| device from the back after passing through | | |
| the interface between the light control layer | | |
| and air | | |
| External light ray at the interface between the | 12.387% | 71.276% |
| light control layer and the compensation | | |
| structure after passing through the light | | |
| control layer | | |
| External light ray at the interface between the | 71.276% | 12.387% |
| compensation structure and the substrate | | |
| after passing through the compensation | | |
| structure | | |
| External light ray at the interface between the | 71.276% | 12.387% |
| cover plate and air after passing through the | | |
| cover plate | | |
| External light ray entering air from the front | 70.563% | 9.909% |
| Proportion of light ray entering air from the | 40.23% | |
| front to the original | | |

From Table 6, it can be seen that the display device 1C has a transmittance of approximately 40% at a viewing angle of 30 degrees.

Table 7, Table 8, and Table 9 show the states of the light rays in each film layer of the display device 1C in another embodiment of the disclosure. The embodiments of Table 7, Table 8, and Table 9 are different from the embodiments of Table 4, Table 5 and Table 6 in that in the embodiments of Table 7, Table 8, and Table 9, a concentration of an absorption material in the light control layer is increased so that the transmittance of the display device 1C at a normal viewing angle is 63%. Table 7 shows the percentage of light ray emitted by the light-emitting diode that remains after passing through each film layer at an output angle of 30 degrees.

TABLE 7

| | P waves in | S waves in |
|---|---|---|
| | light ray | light ray |
| Light ray emitted by a light-emitting diode | 100.000% | 100.000% |
| Light ray at the interface between the cover | 100.000% | 100.000% |
| plate and air after passing through the cover | | |
| plate | | |
| Light ray entering air from the front | 99.000% | 80.000% |
| Proportion of light ray entering air from the | 89.500% | |
| front to the original | | |

It can be seen from Table 7 that the light absorbing structure 20C of the display device 1C is disposed on the second surface 12 of the display panel 100, which can increase the amount of light ray entering air from the front.

Table 8 shows the percentage of light ray emitted by the light-emitting diode that is reflected at the interface between the cover plate and air at a reflection angle of 30 degrees and then re-passes through each film layer at an incident angle of 30 degrees. Following the results in Table 7, approximately 1% of the P-wave and 20% of the S-wave are reflected at the interface between the cover plate and air.

TABLE 8

| | P waves in | S waves in |
|---|---|---|
| | light ray | light ray |
| Light ray reflected at the interface between | 1.000% | 20.000% |
| the cover plate (glass) and air | | |
| Light ray at the interface between the | 1.000% | 20.000% |
| substrate and the compensation structure | | |
| after passing through the substrate (glass) | | |
| Light ray at the interface between the | 20.000% | 1.000% |
| compensation structure and the light control | | |
| layer after passing through the compensation | | |
| structure | | |
| Light ray at the interface between the light | 0.31% | 0.8% |
| control layer and air after passing through the | | |
| light control layer | | |
| Light ray that enters air from the back after | 0.307% | 0.64% |
| passing through the light control layer | | |

| | |
|---|---|
| Proportion of light rays entering air from the | 0.473% |
| back | |

It can be seen from Table 7 and Table 8 that the light control layer 300 and the compensation structure (i.e., the first optical compensation film 410C and the second optical compensation film 420C) may significantly reduce the back-side light leakage, so that the visual effect of the display device 1C is improved.

With reference to FIG. 3 together, the external light ray incident on the display device 1C from the back side of the display device 1C may leave from the front side of the display device 1C after passing through each film layer. Table 9 shows the percentage of external light ray that remains after passing through each film layer at an output angle of 30 degrees in an embodiment. In Table 9, it is assumed that the light ray does not pass through any opaque components.

TABLE 9

| | P waves in | S waves in |
|---|---|---|
| | light ray | light ray |
| External light ray | 100.000% | 100.000% |
| External light ray that enters the display | 99.000% | 80.000% |
| device from the back after passing through | | |
| the interface between the light control layer | | |
| and air | | |
| External light ray at the interface between the | 1.534% | 64.000% |
| light control layer and the compensation | | |
| structure after passing through the light | | |
| control layer | | |
| External light ray at the interface between the | 64.000% | 1.534% |
| compensation structure and the substrate | | |
| after passing through the compensation | | |
| structure | | |
| External light ray at the interface between the | 64% | 1.534% |
| cover plate and air after passing through the | | |
| cover plate | | |
| External light ray entering air from the front | 63.36% | 1.228% |
| Proportion of light ray entering air from the | 32.293% | |
| front to the original | | |

From Table 9, it can be seen that the display device 1C has a transmittance of approximately 32% at a viewing angle of 30 degrees.

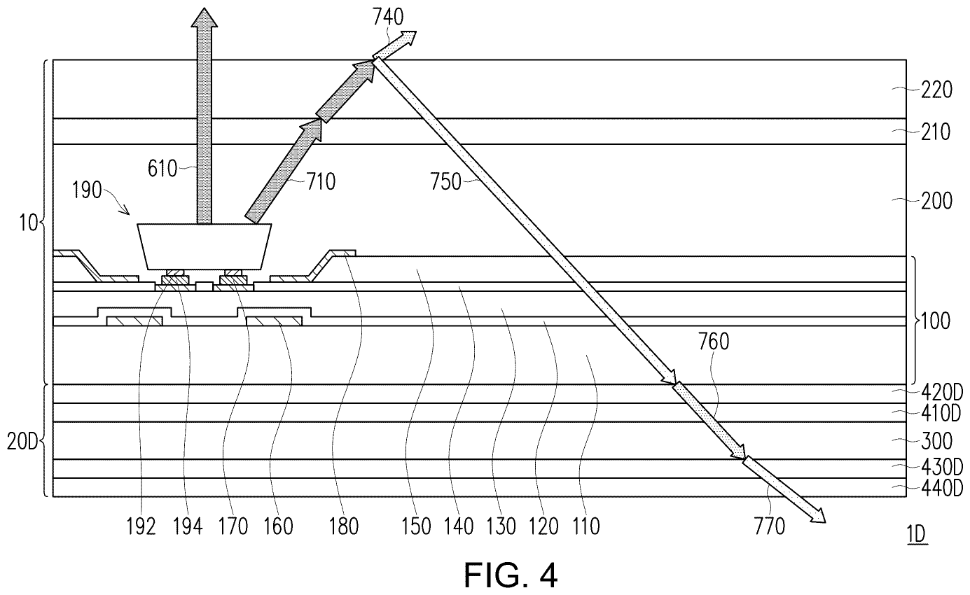

FIG. 4 is a schematic cross-sectional view of a display device 1D according to an embodiment of the disclosure. It should be noted that the reference numerals and a part of the contents in the embodiment of FIG. 3 are also used to describe the embodiment of FIG. 4, in which the same reference numerals are used to represent identical or similar elements, and thus descriptions of the same technical contents are omitted. Please refer to the descriptions of the previous embodiments for the omitted part, which will not be repeated hereinafter.

The difference between the display device 1D of FIG. 4 and the display device 1C of FIG. 3 is that a light absorbing structure 20D of the display device 1D includes the light control layer 300, a first optical compensation film 410D overlapped with the light control layer 300, a second optical compensation film 420D, a third optical compensation film 430D, and a fourth optical compensation film 440D. The light absorbing structure 20D is located on the second surface 12, and the first optical compensation film 410D and the second optical compensation film 420D are located between the light control layer 300 and the circuit substrate 100. The first optical compensation film 410D is located between the light control layer 300 and the second optical compensation film 420D. The third optical compensation film 430D located on the light control layer 300 located between the first optical compensation film 410D and the third optical compensation film 430D. The fourth optical compensation film 440D is located on the third optical compensation film 430D located between the light control layer 300 and the fourth optical compensation film 440D.

In this embodiment, the first optical compensation film 410D, the second optical compensation film 420D, the third optical compensation film 430D, and the fourth optical compensation film 440D may all be referred to as retardation films. Refractive indices of the first optical compensation film 410D in the xyz directions are nx1, ny1, and nz1, respectively, where the direction of nz1 is parallel to a normal direction of the first optical compensation film 410D. Refractive indices of the second optical compensation film 420D in the xyz directions are nx2, ny2, and nz2, respectively, where the direction of nz2 is parallel to a normal direction of the second optical compensation film 420D. Refractive indices of the third optical compensation film 430D in the xyz directions are nx3, ny3, and nz3, respectively, where the direction of nz3 is parallel to a normal direction of the third optical compensation film 430D. Refractive indices of the fourth optical compensation film 440D in the xyz directions are nx4, ny4, and nz4, respectively, where the direction of nz4 is parallel to a normal direction of the fourth optical compensation film 440D. An in-plane retardation R0 of the first optical compensation film 410D is equal to (nx1−ny1)d1, where d1 is a thickness of the first optical compensation film 410D. An in-plane retardation R0 of the second optical compensation film 420D is equal to (nx2−ny2)d1, where d2 is a thickness of the second optical compensation film 420D. An in-plane retardation R0 of the third optical compensation film 430D is equal to (nx3−ny3)d3, where d3 is a thickness of the third optical compensation film 430D. An in-plane retardation R0 of the fourth optical compensation film 440D is equal to (nx4−ny4)d4, where d4 is a thickness of the fourth optical compensation film 440D. In some embodiments, d1, d2, d3, and d4 are each 100 nm to 200 μm. In this embodiment, an absolute value of the in-plane retardation R0 of the first optical compensation film 410D, an absolute value of the in-plane retardation R0 of the second optical compensation film 420D, an absolute value of the in-plane retardation R0 of the third optical compensation film 430D, and an absolute value of the in-plane retardation R0 of the fourth optical compensation film 440D are greater than 130 nm and less than 550 nm. For instance, the absolute value of the in-plane retardation R0 of the first optical compensation film 410D, the absolute value of the in-plane retardation R0 of the second optical compensation film 420D, the absolute value of the in-plane retardation R0 of the third optical compensation film 430D, and the absolute value of the in-plane retardation R0 of the fourth optical compensation film 440D are all in the range of 195 nm to 350 nm, for example, approximately 270 nm. In some embodiments, the absolute value of the in-plane retardation R0 of the first optical compensation film 410D, the absolute value of the in-plane retardation R0 of the second optical compensation film 420D, the absolute value of the in-plane retardation R0 of the third optical compensation film 430D, and the absolute value of the in-plane retardation R0 of the fourth optical compensation film 440D are greater than or equal to the absolute value of the in-plane retardation R0 of the ¼ wavelength wave plate (approximately 137.5 nm). In some embodiments, the first optical compensation film 410D, the second optical compensation film 420D, the third optical compensation film 430D, and the fourth optical compensation film 440D may all be referred to as ½ (or x+½) wavelength wave plates. An angle between a slow axis of the first optical compensation film 410D and a slow axis of the second optical compensation film 420D is in the range of 30° to 60°, for example, approximately 45 degrees. An angle between a slow axis of the third optical compensation film 430D and a slow axis of the fourth optical compensation film 440D is in the range of 30° to 60°, for example, approximately 45 degrees.

With reference to FIG. 4 together, the light ray emitted by the light-emitting diode 190 may enter air after passing through the cover plate 220. Table 10, Table 11, and Table 12 show the states of the light rays in each film layer of the display device 1D in an embodiment of the disclosure. In Table 10, Table 11, and Table 12, it is assumed that film layers other than the light control layer 300, a first compensation structure (i.e., the first optical compensation film 410D and the second optical compensation film 420D), and a second compensation structure (i.e., the third optical compensation film 430D and the fourth optical compensation film 440D) do not absorb light, the in-plane retardation R0 of the first optical compensation film 410D, the in-plane retardation R0 of the second optical compensation film 420C, the in-plane retardation R0 of the third optical compensation film 430D, and the in-plane retardation R0 of the fourth optical compensation film 440D are 270 nm, and an angle between a slow axis of the first optical compensation film 410D and a slow axis of the second optical compensation film 420D is 45 degrees and an angle between a slow axis of the third optical compensation film 430D and a slow axis of the fourth optical compensation film 440D is 45 degrees. In the embodiments of Table 10, Table 11, and Table 12, the transmittance of the display device 1D at a normal viewing angle is 76%. Table 10 shows the percentage of light ray emitted by the light-emitting diode that remains after passing through each film layer at an output angle of 30 degrees.

TABLE 10

| | P waves in | S waves in |
|---|---|---|
| | light ray | light ray |
| Light ray emitted by a light-emitting diode | 100.000% | 100.000% |
| Light ray at the interface between the cover | 100.000% | 100.000% |
| plate and air after passing through the cover | | |
| plate | | |
| Light ray entering air from the front | 99.000% | 80.000% |

| | |
|---|---|
| Proportion of light ray entering air from the | 89.500% |
| front to the original | |

It can be seen from Table 10 that the light absorbing structure 20D of the display device 1D is disposed on the second surface 12 of the display panel 100, which can increase the amount of light ray entering air from the front.

Table 11 shows the percentage of light ray emitted by the light-emitting diode that is reflected at the interface between the compensation structure and air at a reflection angle of 30 degrees and then re-passes through each film layer at an incident angle of 30 degrees. Following the results in Table 10, approximately 1% of the P-wave and 20% of the S-wave are reflected at the interface between the compensation structure and air.

TABLE 11

| | P waves in | S waves in |
|---|---|---|
| | light ray | light ray |
| Light ray reflected at the interface between | 1.000% | 20.000% |
| the cover plate (glass) and air | | |
| Light ray at the interface between the | 1.000% | 20.000% |
| substrate and the first compensation structure | | |
| after passing through the substrate (glass) | | |
| Light ray at the interface between the first | 20.000% | 1.000% |
| compensation structure and the light control | | |
| layer after passing through the first | | |
| compensation structure | | |
| Light ray at the interface between the light | 2.502% | 0.891% |
| control layer and the second compensation | | |
| structure after passing through the light | | |
| control layer | | |
| Light ray at the interface between the second | 0.891% | 2.502% |
| compensation structure and air after passing | | |
| through the second compensation structure | | |
| Light ray that enters air from the back after | 0.882% | 2.012% |
| passing through the second compensation | | |
| structure | | |
| Proportion of light rays entering air from the | 1.442% | |
| back | | |

It can be seen from Table 10 and Table 11 that the light control layer 300, the first compensation structure (i.e., the first optical compensation film 410D and the second optical compensation film 420D), and the second compensation structure (i.e., the third optical compensation film 430D and the fourth optical compensation film 440D) can slightly reduce the back-side light leakage, so the visual effect of the display device 1D is further improved.

With reference to FIG. 4 together, the external light ray incident on the display device 1D from the back side of the display device 1D may leave from the front side of the display device 1D after passing through each film layer. Table 12 shows the percentage of external light ray that remains after passing through each film layer at an output angle of 30 degrees in an embodiment. In Table 12, it is assumed that the light ray does not pass through any opaque components.

TABLE 12

| | P waves in | S waves in |
|---|---|---|
| | light ray | light ray |
| External light ray | 100.000% | 100.000% |
| External light ray that enters the display | 99.000% | 80.000% |
| device from the back after passing through | | |
| the interface between the second | | |
| compensation structure and air | | |
| External light ray at the interface between the | 80.000% | 99.000% |
| second compensation structure and the light | | |
| control layer after passing through the second | | |
| compensation structure | | |
| External light ray at the interface between the | 10.010% | 88.204% |
| light control layer and the first compensation | | |
| structure after passing through the light | | |
| control layer | | |
| External light ray at the interface between the | 88.204% | 10.010% |
| first compensation structure and the substrate | | |
| after passing through the first compensation | | |
| structure | | |
| External light ray at the interface between the | 88.204% | 10.010% |
| cover plate and air after passing through the | | |
| cover plate | | |
| External light ray entering air from the front | 87.322% | 8.008% |
| Proportion of light ray entering air from the | 47.665% | |
| front to the original | | |

From Table 12, it can be seen that the transmittance of the display device ID increases significantly to approximately 47% at a viewing angle of 30 degrees.

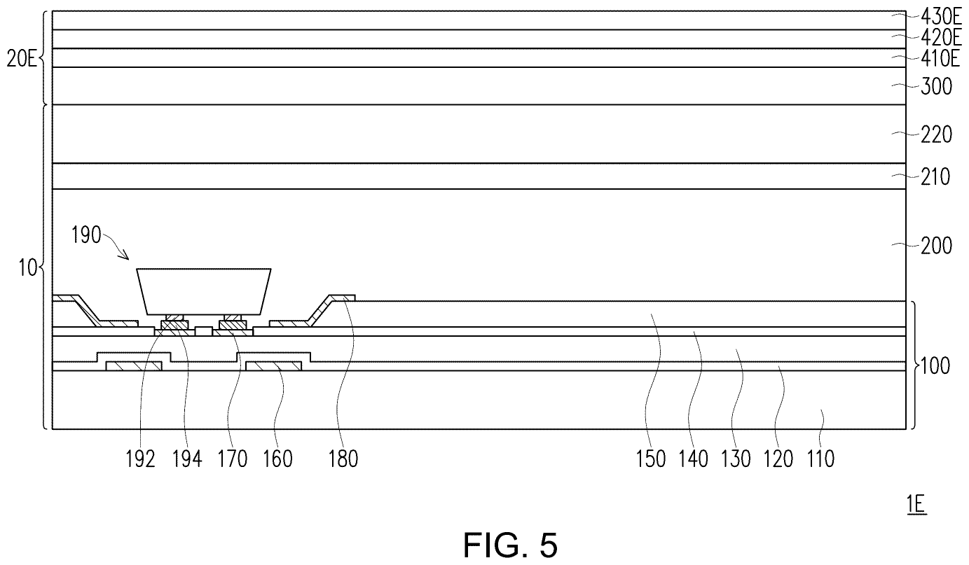

FIG. 5 is a schematic cross-sectional view of a display device 1E according to an embodiment of the disclosure. It should be noted that the reference numerals and a part of the contents in the embodiment of FIG. 1 are also used to describe the embodiment of FIG. 5, in which the same reference numerals are used to represent identical or similar elements, and thus descriptions of the same technical contents are omitted. Please refer to the descriptions of the previous embodiments for the omitted part, which will not be repeated hereinafter.

The difference between the display device 1E of FIG. 5 and the display device 1A of FIG. 1 is that a light absorbing structure 20E of the display device 1E includes the light control layer 300, a first optical compensation film 410E overlapped with the light control layer 300, a second optical compensation film 420E, and a third optical compensation film 430E. The light absorbing structure 20E is located on the first surface 11. The second optical compensation film 420E is located on the first optical compensation film 410E located between the light control layer 300 and the second optical compensation film 420E. The third optical compensation film 430E is located on the second optical compensation film 420E located between the first optical compensation film 410E and the third optical compensation film 430E.

In this embodiment, an absolute value of an in-plane retardation R0 of the first optical compensation film 410E, an absolute value of an in-plane retardation R0 of the second optical compensation film 420E, and an absolute value of an in-plane retardation R0 of the third optical compensation film 430E are greater than 130 nm and less than 550 nm. For instance, the absolute value of the in-plane retardation R0 of the first optical compensation film 410E, the absolute value of the in-plane retardation R0 of the second optical compensation film 420E, and the absolute value of the in-plane retardation R0 of the third optical compensation film 430E are in a range of 130 nm to 195 nm. In some embodiments, the absolute value of the in-plane retardation R0 of the first optical compensation film 410E, the absolute value of the in-plane retardation R0 of the second optical compensation film 420E, and the absolute value of the in-plane retardation R0 of the third optical compensation film 430E are greater than or equal to the absolute value of the in-plane retardation R0 of the ¼ wavelength wave plate (approximately 137.5 nm). An angle between a slow axis of the first optical compensation film 410E and a slow axis of the second optical compensation film 420E is in the range of 60° to 120°. An angle between the slow axis of the second optical compensation film 420E and a slow axis of the third optical compensation film 430E is in the range of 60° to 120°.

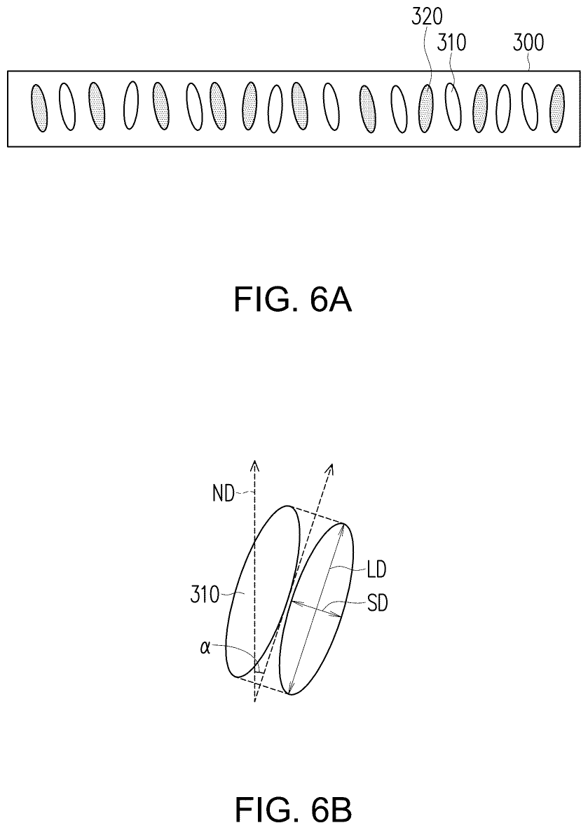

FIG. 6A is a schematic cross-sectional view of the light control layer 300 of a display device according to an embodiment of the disclosure. FIG. 6B is a schematic cross-sectional view of a liquid crystal molecule in the light control layer according to an embodiment of the disclosure. In some embodiments, the light control layer 300 is an electrically controlled birefringence (ECB) liquid crystal cell, a multi-domain vertically aligned (MVAB) liquid crystal cell, or a liquid crystal polymer (LCP) or other types of liquid crystal cells.

With reference to FIG. 6A and FIG. 6B, the light control layer 300 includes a plurality of liquid crystal molecules 310 and dyes 320. In some embodiments, the liquid crystal molecules 310 in the light control layer 300 may be regulated by voltage, so that the light control layer 300 may convert the polarization state of a light ray with a large viewing angle into linear polarization.

The liquid crystal molecules 310 have a long axis LD and a short axis SD. An angle α between a direction of the long axis of the liquid crystal molecules 310 and a normal direction ND of the light control layer 300 is substantially less than or equal to 10 degrees. In this way, the angle between the absorption axis of the light control layer 300 and the normal direction ND is less than or equal to 10 degrees, so as to absorb polarized light whose polarization axis is the Z axis. Absorbing polarized light with the polarization axis along the Z axis may provide favorable optical effect at the expense of minimum transmittance.

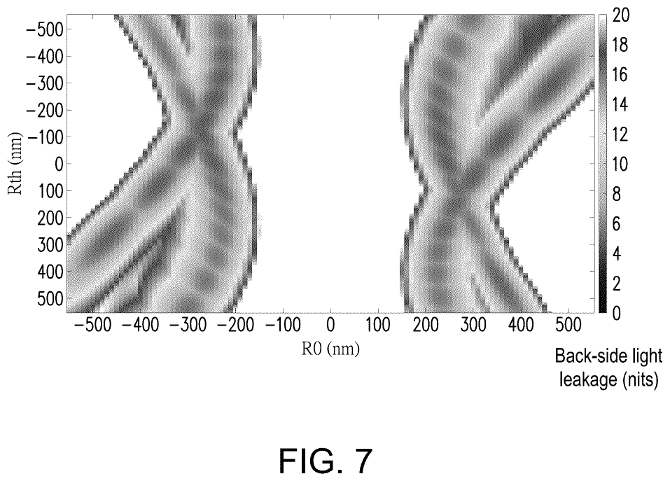

FIG. 7 is a simulation graph of back-side light leakage brightness of a display device and a phase retardation Rth and an in-plane retardation R0 in a thickness direction a first optical compensation film according to an embodiment of the disclosure. The cross-sectional view of the display device in FIG. 7 may refer to the display device 1A in FIG. 1, and FIG. 7 shows that the back-side light leakage has a minimum brightness when the elevation angle (theta) is 75° and the azimuth angle (phi) is 0° to 360°.

With reference to FIG. 1 and FIG. 7, adjusting the thickness direction retardation Rth and the in-plane retardation R0 of the first optical compensation film 410A may affect the back-side light leakage brightness of the display device 1A. The thickness direction retardation Rth of the first optical compensation film 410A is equal to (nx1−nz1)d1, and the in-plane retardation R0 is equal to (nx1−ny1)d1, where d1 is the thickness of the first optical compensation film 410B.

As can be seen from FIG. 7, within some ranges of Rth and R0, the back-side light leakage to the display device 1A may be less than 20 nits.

When R0 of the first optical compensation film 410A is a positive value, the first optical compensation film 410A satisfies the following conditions to reduce the back-side light leakage of the display device 1A:
the thickness direction retardation Rth is less than 150 nm, and 130 nm<R0<(340+(150−Rth)×cot 50°) nm; or the thickness direction retardation Rth is greater than 150 nm, and 130 nm<R0<(340+(Rth−150)×cot 60°) nm.

When R0 of the first optical compensation film 410A is a negative value, the first optical compensation film 410A satisfies the following conditions to reduce the back-side light leakage of the display device 1A:
the thickness direction retardation Rth is less than 150 nm, and −130 nm>R0>−[(340+(150−Rth)×cot 50°)] nm; or
the thickness direction retardation Rth is greater than 150 nm, and −130 nm>R0>−[(340+(Rth−150)×cot 60°)] nm.

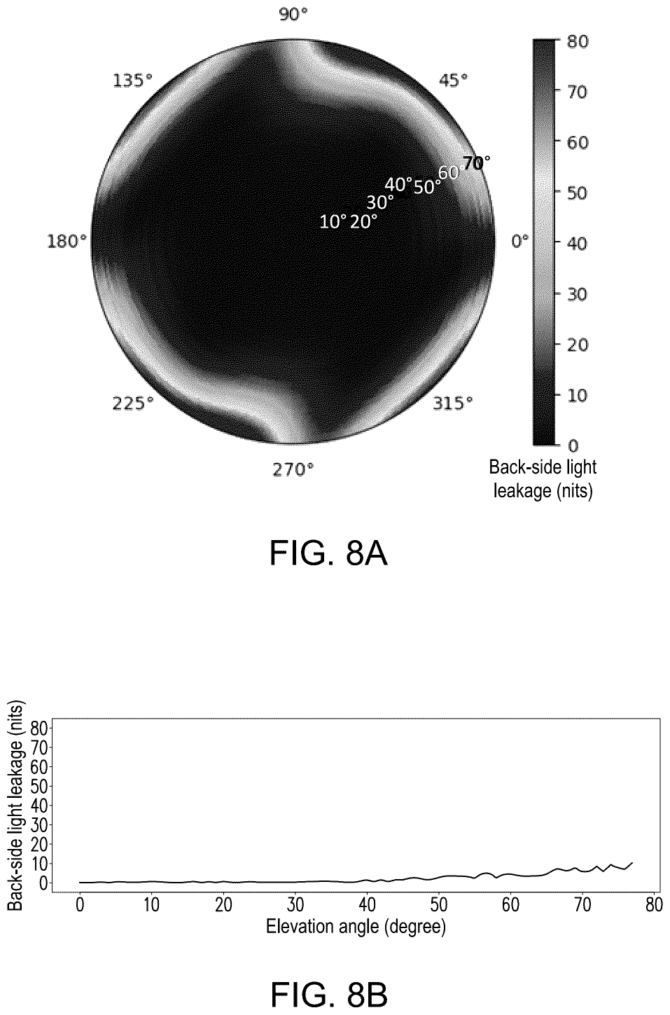

FIG. 8A is a relative brightness distribution of a display device at various viewing angles according to an embodiment of the disclosure. FIG. 8B is a curve chart of an elevation angle (theta) and back-side light leakage of a display device when an azimuth angle (phi) is 0°. FIG. 8A and FIG. 8B correspond to the display device 1A of FIG. 1, where R0 of the first optical compensation film 410A is −250 nm. The Nz of the first optical compensation film 410A is 0.6, where Nz is equal to R0/Rth. The Rth′ of the first optical compensation film 410A is −275 nm, where Rth′ is equal to ((nx1+ny1)/2−nz1)d1. In the embodiments of FIG. 8A and FIG. 8B, the front viewing angle brightness of the display device is 1000 nits. In this embodiment, in the range of the elevation angle of 0° to 81° and the azimuth angle of 0° to 360°, a maximum value of the back-side light leakage is 111.2 nits, and a minimum value of the back-side light leakage is 0. In this embodiment, a light leakage value at the normal viewing angle is 0.2 nits.

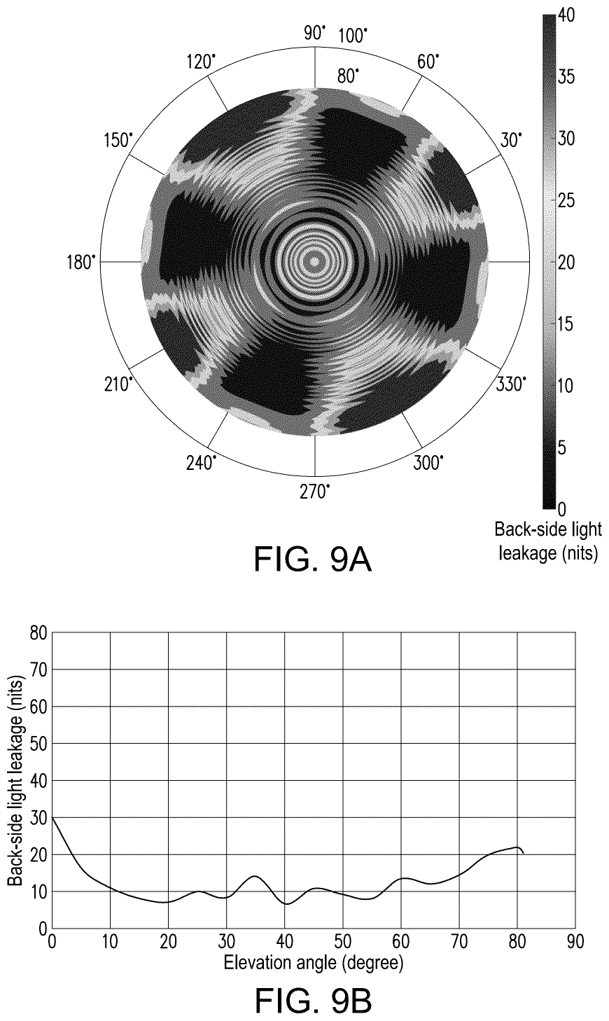

FIG. 9A is a relative brightness distribution of a display device at various viewing angles according to an embodiment of the disclosure. FIG. 9B is a curve chart of an elevation angle (theta) and back-side light leakage of a display device when an azimuth angle (phi) is 0°. FIG. 9A and FIG. 9B also correspond to the display device 1A of FIG. 1, and the difference lies in that the properties of the first optical compensation film 410A are adjusted. In the embodiments of FIG. 9A and FIG. 9B, R0 of the first optical compensation film 410A is −310 nm, Rth is −60 nm, and Rth′ is 9.5 nm. In the embodiments of FIG. 9A and FIG. 9B, the front viewing angle brightness of the display device is 1000 nits.

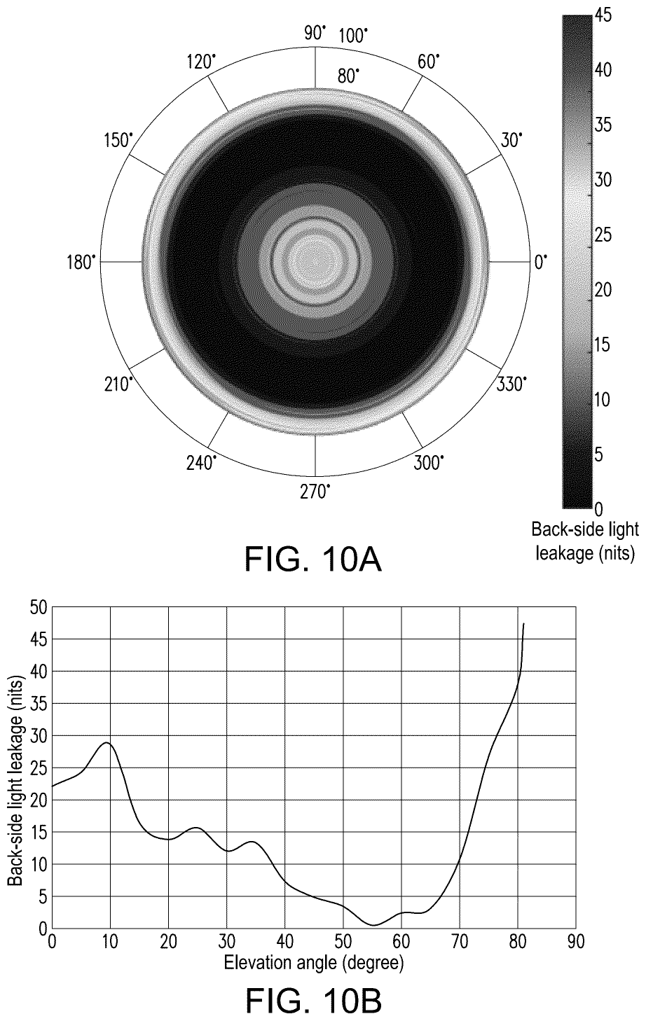

FIG. 10A is a relative brightness distribution of a display device at various viewing angles according to an embodiment of the disclosure. FIG. 10B is a curve chart of an elevation angle (theta) and back-side light leakage of a display device when an azimuth angle (phi) is 0°. FIG. 10A and FIG. 10B correspond to the display device 1B of FIG. 2, where R0 of the first optical compensation film 410B is 270 nm, and R0 of the second optical compensation film 420B is 270 nm. The angle between the slow axis of the first optical compensation film 410B and the slow axis of the second optical compensation film 420B is 45 degrees. In the embodiments of FIG. 10A and FIG. 10B, the front viewing angle brightness of the display device is 1000 nits.

In view of the foregoing, the light absorbing structure includes the light control layer and the optical compensation films. The angle between the absorption axis of the light control layer and the normal direction is less than or equal to 10 degrees, and the absolute value of the in-plane retardation R0 of each optical compensation film is greater than 130 nm and less than 550 nm. Therefore, the light absorbing structure may be used to effectively address the back-side light leakage problem of the display device.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A light absorbing structure for a display device comprising:
a light control layer, wherein an angle between an absorption axis of the light control layer and a normal direction of the light control layer is less than or equal to 10 degrees; and
a first optical compensation film overlapped with the light control layer, wherein an absolute value of an in-plane retardation R0 of the first optical compensation film is greater than 130 nm and less than 550 nm.

2. The light absorbing structure according to claim 1, wherein the R0 of the first optical compensation film is a positive value, and the first optical compensation film satisfies the following conditions:
a thickness direction retardation Rth is less than 150 nm, and 130 nm<R0<(340+(150−Rth)×cot 50°) nm; or
the thickness direction retardation Rth is greater than 150 nm, and 130 nm<R0<(340+(Rth−150)×cot 60°) nm.

3. The light absorbing structure according to claim 1, wherein the R0 of the first optical compensation film is a negative value, and the first optical compensation film satisfies the following conditions:
a thickness direction retardation Rth is less than 150 nm, and −130 nm>R0>−[(340+(150−Rth)×cot 50°)] nm; or
the thickness direction retardation Rth is greater than 150 nm, and −130 nm>R0>−[(340+(Rth−150)×cot 60°)] nm.

4. The light absorbing structure according to claim 1, further comprising:
a second optical compensation film located on the first optical compensation film located between the light control layer and the second optical compensation film, wherein an angle between a slow axis of the first optical compensation film and a slow axis of the second optical compensation film is in a range of 30° to 60°, wherein the absolute value of the in-plane retardation R0 of the first optical compensation film and an absolute value of an in-plane retardation R0 of the second optical compensation film are in a range of 195 nm to 350 nm.

5. The light absorbing structure according to claim 1, further comprising:
a second optical compensation film located on the first optical compensation film located between the light control layer and the second optical compensation film, wherein an angle between a slow axis of the first optical compensation film and a slow axis of the second optical compensation film is 60° to 120°; and
a third optical compensation film located on the second optical compensation film located between the first optical compensation film and the third optical compensation film, wherein an angle between a slow axis of the second optical compensation film and a slow axis of the third optical compensation film is 60° to 120°, wherein the absolute value of the in-plane retardation R0 of the first optical compensation film, an absolute value of an in-plane retardation R0 of the second optical compensation film, and an absolute value of an in-plane retardation R0 of the third optical compensation film are in a range of 130 nm to 195 nm.

6. The light absorbing structure according to claim 1, wherein the light control layer comprises a plurality of liquid crystal molecules and dyes, wherein an angle between a direction of a long axis of the liquid crystal molecules and the normal direction of the light control layer is substantially less than or equal to 10 degrees.

7. The light absorbing structure according to claim 1, wherein the light absorbing structure is disposed in a display panel or is disposed on the display panel.

8. A display device, comprising:
a display panel having a first surface and a second surface opposite to the first surface, wherein the first surface is a display surface of the display panel; and
a light absorbing structure located on the first surface or the second surface of the display panel and comprising:
a light control layer, wherein an angle between an absorption axis of the light control layer and a normal direction of the light control layer is less than or equal to 10 degrees; and
a first optical compensation film overlapped with the light control layer, wherein an absolute value of an in-plane retardation R0 of the first optical compensation film is greater than 130 nm and less than 550 nm.

9. The display device according to claim 8, further comprising:
an anti-reflective film located on the first surface of the display panel, wherein
when the light absorbing structure is located on the first surface of the display panel, the light absorbing structure is located between the anti-reflective film and the display panel, and
when the light absorbing structure is located on the second surface of the display panel, the display panel is located between the anti-reflective film and the light absorbing structure.

10. The display device according to claim 8, further comprising:
a second optical compensation film located on the first optical compensation film located between the light control layer and the second optical compensation film, wherein an angle between a slow axis of the first optical compensation film and a slow axis of the second optical compensation film is in a range of 30° to 60°.

11. The display device according to claim 10, wherein the light absorbing structure is located on the second surface of the display panel and further comprises:
a third optical compensation film located on the light control layer located between the first optical compensation film and the third optical compensation film; and
a fourth optical compensation film located on the third optical compensation film located between the light control layer and the fourth optical compensation film, wherein an angle between a slow axis of the third optical compensation film and a slow axis of the fourth optical compensation film is 30° to 60°.

12. The display device according to claim 10, wherein the absolute value of the in-plane retardation R0 of the first optical compensation film and an absolute value of an in-plane retardation R0 of the second optical compensation film are in a range of 195 nm to 350 nm.

13. The display device according to claim 8, wherein the light absorbing structure further comprises:
a second optical compensation film located on the first optical compensation film located between the light control layer and the second optical compensation film, wherein an angle between a slow axis of the first optical compensation film and a slow axis of the second optical compensation film is 60° to 120°; and
a third optical compensation film located on the second optical compensation film located between the first optical compensation film and the third optical compensation film, wherein an angle between a slow axis of the second optical compensation film and a slow axis of the third optical compensation film is 60° to 120°, wherein the absolute value of the in-plane retardation R0 of the first optical compensation film, an absolute value of an in-plane retardation R0 of the second optical compensation film, and an absolute value of an in-plane retardation R0 of the third optical compensation film are in a range of 130 nm to 195 nm.

14. The display device according to claim 8, wherein the display panel comprises:
a circuit substrate having the second surface;
a light-emitting diode electrically connected to the circuit substrate; and
a cover plate having the first surface, wherein the light-emitting diode is located between the circuit substrate and the cover plate, wherein the light absorbing structure is located on the first surface, and the light control layer is located between the first optical compensation film and the cover plate.

15. The display device according to claim 8, wherein the display panel comprises:
a circuit substrate having the second surface;
a light-emitting diode electrically connected to the circuit substrate; and
a cover plate having the first surface, wherein the light-emitting diode is located between the circuit substrate and the cover plate, wherein the light absorbing structure is located on the second surface, and the first optical compensation film is located between the light control layer and the circuit substrate.

16. The display device according to claim 8, wherein an absorption rate of the light control layer to a P wave in light emitted by the display panel is greater than an absorption rate of the light control layer to a S wave in the light emitted by the display panel.
